(19) United States
(12) Patent Application Publication
(10) Pub. No.: US 2012/0048370 A1
(43) Pub. Date: Mar. 1, 2012

(54) SOLAR CELL

(76) Inventors: Hyungseok KIM, Seoul (KR); Kwangsun Ji, Seoul (KR); Youngjoo Eo, Seoul (KR); Heonmin Lee, Seoul (KR); Choul Kim, Seoul (KR); Hojung Syn, Seoul (KR); Wonseok Choi, Seoul (KR); Kihoon Park, Seoul (KR); Junghoon Choi, Seoul (KR); Hyunjin Yang, Seoul (KR)

(21) Appl. No.: 13/216,061

(22) Filed: Aug. 23, 2011

(30) Foreign Application Priority Data
Aug. 26, 2010 (KR) 10-2010-0082900

(51) Int. Cl. H01L 31/0376

(52) U.S. Cl. 136/258

(57) ABSTRACT

A solar cell includes a crystalline semiconductor substrate containing a first impurity of a first conductive type, a first non-crystalline impurity semiconductor region directly contacting with the crystalline semiconductor substrate to form a p-n junction with the crystalline semiconductor substrate and including a first portion in which a second impurity of a second conductive type is doped with a first impurity doping concentration and a second portion in which the second impurity is doped with a second impurity doping concentration, the first impurity doping concentration being less than an impurity doping concentration of the crystalline semiconductor substrate and the second impurity doping concentration being greater than the impurity doping concentration of the crystalline semiconductor substrate, a first electrode connected to the first non-crystalline impurity semiconductor region, and a second electrode connected to the crystalline semiconductor substrate.

### CROSS-REFERENCE TO RELATED APPLICATION

This application claims priority to and the benefit of Korean Patent Application No. 10-2010-0082900, filed in the Korean Intellectual Property Office on Aug. 26, 2010, the entire contents of which are incorporated herein by reference.

### BACKGROUND OF THE INVENTION

(a) Field of the Invention

Embodiments of the invention relate to a solar cell.

(b) Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts that have different conductive types, such as a p-type and an n-type, and form a p-n junction, and electrodes respectively connected to the semiconductor parts of the different conductive types.

When light is incident on the solar cell, electron-hole pairs are generated in the semiconductor parts. The electrons move to the n-type semiconductor part and the holes move to the p-type semiconductor part, and then the electrons and holes are collected by the electrodes connected to the n-type semiconductor part and the p-type semiconductor part, respectively. The electrodes are connected to each other using electric wires to thereby obtain electric power.

### SUMMARY OF THE INVENTION

According to an aspect of the invention, a solar cell may include a crystalline semiconductor substrate containing a first impurity of a first conductive type, a first non-crystalline impurity semiconductor region directly contacting with the crystalline semiconductor substrate to form a p-n junction with the crystalline semiconductor substrate and including a first portion in which a second impurity of a second conductive type is doped with a first impurity doping concentration and a second portion in which the second impurity is doped with a second impurity doping concentration, the first impurity doping concentration being less than an impurity doping concentration of the crystalline semiconductor substrate and the second impurity doping concentration being greater than the impurity doping concentration of the crystalline semiconductor substrate, a first electrode connected to the first non-crystalline impurity semiconductor region, and a second electrode connected to the crystalline semiconductor substrate.

The first portion may be positioned on the crystalline semiconductor substrate and the second portion may be positioned on the first portion.

The first impurity doping concentration may be substantially 1×10¹⁰ atoms/cm³ to 1×10¹⁵ atoms/cm³ and the second impurity doping concentration may be substantially 1×10¹⁸ atoms/cm³ to 1×10²¹ atoms/cm³.

The first portion of the first non-crystalline impurity semiconductor region may have a thickness equal to a thickness of the second portion of the first non-crystalline impurity semiconductor region.

The first non-crystalline impurity semiconductor region may further include a third portion positioned between the first portion of the first non-crystalline impurity semiconductor region and the second portion of the first non-crystalline impurity semiconductor region and may have a third impurity doping concentration different from the first and second impurity doping concentrations.

The third impurity doping concentration may be greater than the first impurity doping concentration and less than second impurity doping concentration.

The third impurity doping concentration may be substantially 1×10¹⁶ atoms/cm³ to 1×10¹⁷ atoms/cm³.

The third portion of the first non-crystalline impurity semiconductor region may have a thickness that is half of a thickness of the first portion of the first non-crystalline impurity semiconductor region.

The thickness of the first portion may be equal to the thickness of the second portion.

The first non-crystalline impurity semiconductor region may be positioned on a surface of the crystalline semiconductor substrate, on which light is not incident.

The solar cell may further include a second non-crystalline impurity semiconductor region including a first portion in which a third impurity of a third conductive type is doped with a third impurity doping concentration and a second portion in which the third impurity is doped with a fourth impurity doping concentration, the fourth impurity doping concentration may be greater than the third impurity doping concentration.

The first portion of the second non-crystalline impurity semiconductor region may be positioned on the crystalline semiconductor substrate and the second portion of the second non-crystalline impurity semiconductor region may be positioned on the first portion of the second non-crystalline impurity semiconductor region.

The third impurity doping concentration may be equal to the first impurity doping concentration and the fourth impurity doping concentration may be equal to the second impurity doping concentration.

The second non-crystalline impurity semiconductor region may further include a third portion positioned between the first portion of the second non-crystalline impurity semiconductor region and the second portion of the second non-crystalline impurity semiconductor region and may have a fifth impurity doping concentration different from the third and fourth impurity doping concentrations.

The second non-crystalline impurity semiconductor region may be positioned on a same surface as the first non-crystalline impurity semiconductor region and may be separated from the first non-crystalline impurity semiconductor region, and the second electrode may be connected to the crystalline semiconductor substrate through the second non-crystalline impurity semiconductor region.

The second non-crystalline impurity semiconductor region may be positioned on a surface of the crystalline semiconductor substrate, on which light is not incident.

The second non-crystalline impurity semiconductor region may face the first non-crystalline impurity semiconductor region with respect to the crystalline semiconductor substrate and may be further positioned on a different surface from the first non-crystalline impurity semiconductor region.

The second non-crystalline impurity semiconductor region may be positioned on a different surface from the first non-crystalline impurity semiconductor region.

The second non-crystalline impurity semiconductor region may be positioned on a surface of the crystalline semiconductor substrate, on which light is incident.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial sectional view of a solar cell according to an embodiment of the invention; and

FIG. 2 is a graph illustrating a relationship between an impurity doping concentration and a specific resistance.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

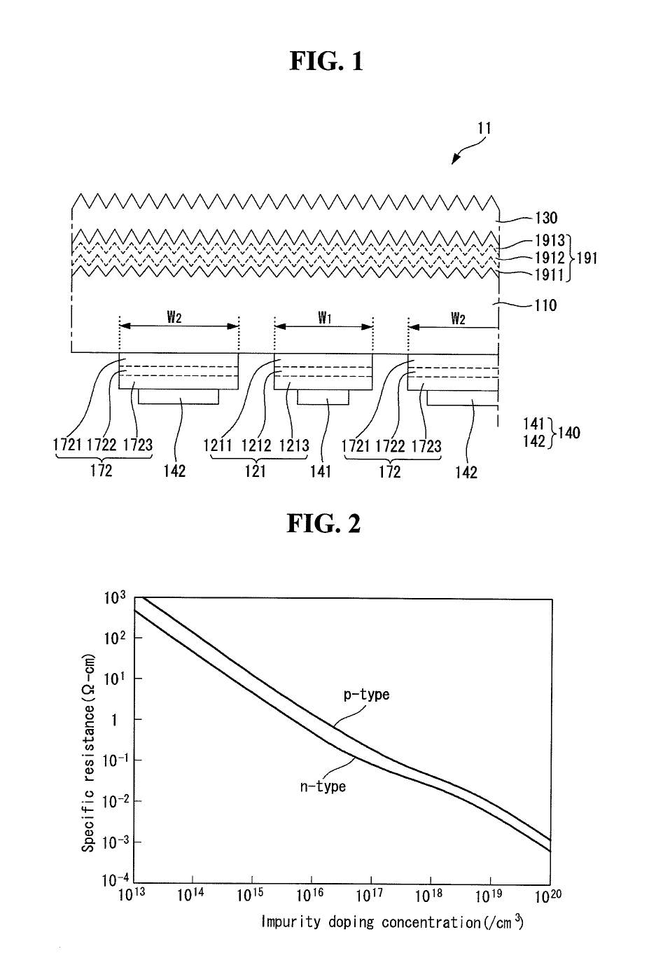

A solar cell according to an embodiment of the invention is described in detail with reference to FIG. 1.

FIG. 1 is a partial perspective view of a solar cell according to an embodiment of the invention.

As shown in FIG. 1, a solar cell 11 according to an example embodiment of the invention includes a substrate 110, a front impurity region 191 positioned on an incident surface (hereinafter, referred to as “a front surface”) of the substrate 110 on which light is incident, an anti-reflection layer 130 positioned on the front impurity portion 191, a plurality of first back impurity regions 121 positioned on a surface (hereinafter, referred to as “a back surface”) of the substrate 110, on which the light is not incident, opposite the front surface of the substrate 110, a plurality of second back impurity regions 172 that are positioned on the back surface of the substrate 110 to be separated from the plurality of first back impurity regions 121, and an electrode part 140 including a plurality of first electrodes 141 respectively positioned on the plurality of first back impurity regions 121 and a plurality of second electrodes 142 respectively positioned on the plurality of second back impurity regions 172.

The substrate 110 is a semiconductor substrate formed of, for example, first conductive type silicon, such as an n-type silicon, though not required. Silicon used in the substrate 110 may be crystalline silicon such as single crystal silicon and polycrystalline silicon. When the substrate 110 is of an n-type, the substrate 110 is doped with impurities of a group V element such as phosphor (P), arsenic (As), and antimony (Sb). Alternatively, the substrate 110 may be of a p-type, and/or be formed of another semiconductor materials other than silicon. When the substrate 110 is of the p-type, the substrate 110 is doped with impurities of a group III element such as boron (B), gallium (Ga), and indium (In).

The front surface of the substrate 110 may be textured to form a textured surface corresponding to an uneven surface or having uneven characteristics. Thereby, the front impurity region 191 and the anti-reflection layer 130 on the front surface of the substrate 110 have the textured surface.

The front impurity regions 191 on the front surface of the substrate 110 are formed of amorphous silicon (a-Si) and contain impurities of a conductive type (for example, an n-type) equal to that of the substrate 110. Thereby, the front impurity regions 191 are referred to as non-crystalline impurity semiconductor regions.

An impurity doping concentration of the front impurity region 191 is continuously or non-continuously varied along a vertical direction, that is, a thickness direction of the front impurity region 191. When the impurity doping concentration is continuously varied, the impurity doping concentration of the front impurity region 191 is linearly or non-linearly varied.

That is, the impurity doping concentration increases from a portion (i.e., a boundary surface) at which a surface of the substrate 110 and the front impurity region 191 are contacted to each other to a portion (i.e., an upper surface of the front impurity region 191) opposite the portion (the boundary surface). Thereby, the impurity doping concentration increases according to a position (a thickness) of the front impurity region 191 from the boundary surface to the anti-reflection layer 130.

In this instance, the front impurity region 191 is divided into three portions based on variation of the impurity doping concentration. For example, the front impurity region 191 includes a first portion 1911 with a low impurity doping concentration of about 1×10¹⁰ atoms/cm³ to 1×10¹⁵ atoms/cm³, a second portion 1912 with an impurity doping concentration of about 1×10¹⁶ atoms/cm³ to 1×10¹⁷ atoms/cm³, and a third portion 1913 with a high impurity doping concentration of about 1×10¹⁸ atoms/cm³ to 1×10²¹ atoms/cm³. Each of the first to third portions 1911-1913 may have one fixed impurity doping concentration selected in each of the three regions or have an impurity doping concentration that is further continuously or non-continuously changed within each of the three regions.

Thereby, in the front impurity region 191, an intrinsic semiconductor characteristic increases as a position of the front impurity region 191 is closer to the substrate 110 and an extrinsic semiconductor characteristic increases as a position of the front impurity region 191 is closer to the anti-reflection layer 130.

The first portion 1911 of the front impurity region 191 may have the impurity doping concentration that is less than that of the substrate 110, and the third portion 1913 of the front impurity region 191 may have the impurity doping concentration that is greater than that of the substrate 110. The second portion 1912 of the front impurity region 191 may have the impurity doping concentration that is substantially equal to that of the substrate 110.

The first portion 1911 of the front impurity region 191 has a thickness of about 2 nm to 10 nm, the second portion 1912 of the front impurity region 191 has a thickness of about 1 nm to 5 nm, and the third portion 1913 of the front impurity region 191 has a thickness of about 2 nm to 10 nm. Thereby, the total thickness of the front impurity region 191 is about 5 nm to 25 nm. As described above, the thicknesses of the first and third portions 1911 and 1913 may be substantially equal to each other and the thickness of the second portion 1912 may be half the thickness of each of first and third portions 1911 and 1913

In this instance, the first portion 1911 is in contact with the substrate 110 and the third portion 1913 is adjacent to the anti-reflection layer 130.

Since the first portion 1911 having the strongest intrinsic semiconductor characteristic of the first to third portions 1911-1913 is directly contacted with a surface of the substrate 110 and has the lowest impurity doping concentration of the first to third portions 1911-1913, the first portion 1911 of the front impurity region 191 performs a passivation operation that converts a defect, for example, dangling bonds existing on and/or around the surface of the substrate 110 into stable bonds to thereby prevent or reduce a recombination and/or a disappearance of charges moving to the front surface of the substrate 110 resulting from the defect.

By the third portion 1913 having the strongest extrinsic semiconductor characteristic of the first to third portions 1911-1913, a potential barrier resulting from a difference between impurity concentrations of the substrate 110 and the third portion 1913 is formed, and thereby the movement of charges (for example, holes) to the front surface of the substrate 110 is prevented or reduced. Thus, a front surface field effect is obtained by returning the charges moving to the front surface of the substrate 110 to the back surface of the substrate 110 by the potential barrier of the third portion 1913. Thereby, the third portion 1913 performs a front surface field function. Finally, by the functions of first and third portions 1911 and 1913, the movement of undesired charges (e.g., holes) to the front surface of the substrate 110 and the recombination and/or disappearance of the charges (e.g., holes) on or around the front surface of the substrate 110 are prevented or reduced.

The second portion 1912 positioned between the first and third portions 1911 and 1913 decreases an energy band gap difference between the first and third portions 1911 and 1913, and thereby an energy band gap is gently, incrementally or gradually changed from the first portion 1911 to the third portion 1913. Thus, the charges easily move from the first portion 1911 to the third portion 1913.

When the total thickness of the front impurity region 191 is more than about 5 nm, fields for the front surface field function are more stably generated to more improve the front surface field function.

When the total thickness of the front impurity region 191 is less than about 25 nm, an amount of light absorbed in the front impurity region 191 is reduced. Hence, an amount of light incident in the substrate 110 may increase.

Since the front impurity region 191 of a single-layered structure performs the passivation function and the front surface field function by varying the impurity doping concentration, the solar cell 11 according to example embodiment of the invention is not required to include a separate passivation region (for example, an intrinsic amorphous silicon layer) and a front surface field region for the respective passivation function and the front surface field function at the front surface of the substrate 110.

The front impurity region 191 may be formed by a film formation method such as a plasma enhanced chemical vapor deposition (PECVD) method and so on, by using silane (SiH₄), hydrogen (H₂), phosphine (PH₃), etc. In this instance, silane (SiH₄) and hydrogen (H₂) are used for a formation of the amorphous silicon layer and phosphine (PH₃) is used for doping an impurity of the n-type. Thereby, by changing an amount of the impurity doping material (e.g., phosphine) injected into a chamber for forming the front impurity region 191 in process of time (or in situ), the first to third portions 1911 to 1913 of the front impurity region 191, each of which having a desired thickness and a desired impurity doping concentration may be formed.

The loss amount of charges is decreased by the passivation function and the front surface field function of the front impurity region 191 positioned on the front surface of the substrate 110, and thereby an efficiency of the solar cell 11 is improved. In addition, since a separate passivation region is not required, the time and cost for manufacturing the solar cell 11 are reduced.

Since the solar cell 11 shown in FIG. 1 includes the first and second electrodes 141 and 142 all positioned on a surface (a non-incident surface) of the substrate 110, on which light is not incident, charges are not outputted through the front impurity region 191 to an external device. Thereby, in an alternative example, the front impurity region 191 need not include the second portion 1912. That is, in the alternative example, the front impurity region 191 may be divided only into the first portion 1911 having an impurity doping concentration of about 1×10¹⁰ atoms/cm³ to 1×10¹⁵ atoms/cm³ and the third portion 1913 having an impurity doping concentration of about 1×10¹⁸ atoms/cm³ to 1×10²¹ atoms/cm³. In the embodiment of the invention as described above, the first portion 1911 may have a thickness of about 2 nm to 10 nm and the third portion 1913 may have a thickness of about 2 nm to 10 nm.

Also in the embodiment of the invention, each of the impurity doping concentrations of the first and third portions 1911 and 1913 may have one fixed impurity doping concentration selected in each of the predetermined regions or have an impurity doping concentration continuously or non-continuously changed within each of the predetermined regions.

In this instance, the total thickness of the front impurity region 191 decreases, and thereby a manufacturing time of the front impurity region 191 decreases.

The anti-reflection layer 130 on the front impurity region 191 reduces a reflectance of light incident on the solar cell 11 and increases selectivity of a predetermined wavelength band, thereby increasing the efficiency of the solar cell 11.

The anti-reflection layer 130 may be formed of at least one of silicon nitride (SiNx), amorphous silicon nitride (a-SiNx) and silicon oxide (SiOx). The anti-reflection layer 130 may have a thickness of about 70 nm to 90 nm.

When the anti-reflection layer 130 has the thickness in a range of about 70 nm to 90 nm, the anti-reflection layer 130 has good transmissivity to more increase an amount of light incident on the substrate 110.

In the embodiment of the invention, the anti-reflection layer 130 has a single-layered structure, but the anti-reflection layer 130 may have a multi-layered structure such as a double-layered structure in other embodiments. The anti-reflection layer 130 may be omitted, if desired.

The plurality of first back impurity regions 121 and the plurality of second back impurity regions 172 are positioned on the back surface of the substrate 110 to be separated from each other and extend parallel to each other in a predetermined direction.

As shown in FIG. 1, each first back impurity region 121 and each second back impurity region 172 are alternately positioned on the back surface of the substrate 110.

Each first back impurity region 121 is of a second conductive type (for example, a p-type) opposite the conductive type of the substrate 110. Each first impurity region 121 is formed of a non-crystalline semiconductor, for example, amorphous silicon different from the substrate 110.

Thus, the plurality of first back impurity regions 121 form a p-n junction with the substrate 110 and function as emitter regions. In addition, each of the first back impurity regions 121 is made of a semiconductor different from the substrate 110 or a semiconductor having a different characteristic from the substrate 110, and thereby each first back impurity region 121 forms a hetero junction. Thereby, the plurality of first back impurity regions 121 are non-crystalline impurity semiconductor regions.

Each second back impurity region 172 is of the first conductive type (for example, an n-type) that is the same as the conductive type of the substrate 110. Like the first back impurity regions 121, the second back impurity regions 172 are formed of a non-crystalline semiconductor such as amorphous silicon. Thus, the plurality of second back impurity regions 172 and the substrate 110 also form a hetero junction, and the plurality of second back impurity regions 172 are non-crystalline impurity semiconductor regions.

By a built-in potential difference resulting from the p-n junction between the substrate 110 and the first back impurity regions 121, electrons and holes produced by light incident on the substrate 110 move to the n-type semiconductor and the p-type semiconductor, respectively. Thus, when the substrate 110 is of the n-type and the first back impurity regions 121 are of the p-type, the electrons move to the second back impurity regions 172 and the holes move to the first back impurity regions 121.

Similar to the front impurity region 191, impurity doping concentrations of each first back impurity region 121 and each second back impurity region 172 are continuously or non-continuously varied along a vertical direction, that is, a thickness direction of each of the first and second back impurity regions 121 and 172. When each of the impurity doping concentrations of the first and second back impurity regions 121 and 172 is continuously varied, each of the impurity doping concentrations of the front and second impurity regions 121 and 172 is linearly or non-linearly varied. In this instance, each of the impurity doping concentrations of the first and second back impurity regions 121 and 172 increases according to a position (in a thickness) of each back impurity region 121 and 172 from the substrate 110 to the electrode part 140.

Like the front impurity region 191, each of the first and second back impurity regions 121 and 172 is divided into three portions 1211, 1212 and 1213 and 1721, 1722 and 1723, respectively, based on a variation of the impurity doping concentration.

In the embodiment of the invention, the impurity doping concentrations of the first and third portions 1211, 1721, 1213 and 1723 of the first and second back impurity regions 121 and 172, respectively, are substantially equal to the impurity doping concentrations of the first and third portions 1911 and 1913 of the front impurity region 191, respectively. The impurity doping concentrations of the second portions 1212 and 1722 of the first and second back impurity regions 121 and 172 are substantially equal to the impurity doping concentration of the second portion 1912 of the front impurity region 191, respectively.

Thus, each of the first portions 1211 and 1721 of the first and second back impurity regions 121 and 172 may have the impurity doping concentration of about 1×10¹⁰ atoms/cm³ to 1×10¹⁵ atoms/cm³, each of the second portions 1212 and 1722 of the first and second back impurity regions 121 and 172 may have the impurity doping concentration of about 1×10¹⁶ atoms/cm³ to 1×10¹⁷ atoms/cm³, and each of the third portions 1213 and 1723 of the first and second back impurity regions 121 and 172 may have the impurity doping concentration of about 1×10¹⁸ atoms/cm³ to 1×10²¹ atoms/cm³. Similar to each of the first to third portions 1911-1913, each of the first and third portions 1211-1213 and 1721-1723 may have one fixed impurity doping concentration selected in each of the predetermined three regions or have an impurity doping concentration continuously or non-continuously changed within each of the predetermined three regions.

In addition, thicknesses of the first and third portions 1211, 1721, 1213 and 1723 of the first and second back impurity regions 121 and 172, respectively, are substantially equal to the thicknesses of the first and third portions 1911 and 1913 of the front impurity region 191, respectively. The thicknesses of the second portions 1212 and 1722 of the first and second back impurity regions 121 and 172 are substantially equal to the thickness of the second portion 1912 of the front impurity region 191, respectively.

Thereby, each of the first and third portions 1211, 1721, 1213 and 1723 of the first and second back impurity regions 121 and 172, respectively, may have the thickness of about 2 nm to 10 nm and each of the second portions 1212 and 1722 of the first and second back impurity regions 121 and 172 may have the thickness of about 1 nm to 5 nm. The total thicknesses of the first and second back impurity regions 121 and 172 are about 5 nm to 25 nm, respectively.

The first portions 1211 and 1721 of the first and second back impurity regions 121 and 172 may have the impurity doping concentration less than that of the substrate 110, respectively and the third portions 1213 and 1723 of the first and second back impurity regions 121 and 172 may have the impurity doping concentration more than that of the substrate 110, respectively. The second portions 1212 and 1722 of the first and second back impurity regions 121 and 172 may have the impurity doping concentration substantially equal to that of the substrate 110, respectively.

Like the front impurity region 191, since an amount of the impurity doped in the first portions 1211 and 1721, and causing the defects such as the dangling bonds is less than the remaining portions 1212, 1213, 1722 and 1723, the first portions 1211 and 1721 with the lowest impurity doping concentration effectively performs as a passivation function.

As shown in FIG. 2, as the impurity doping concentration of the impurity of an n-type and the impurity doping concentration of the impurity of a p-type increase, respectively, a specific resistance is reduced to increase conductivity and ohmic contact. Thus, the third portions 1213 and 1723 of the first and second back impurity regions 121 and 172 by the high impurity doping concentration have high conductivity and good contact characteristics, as compared with the first and second portions 1211, 1212, 1721, and 1722. Accordingly, charge transfer ability and contact power with the electrode part 140 of the first and second back impurity regions 121 and 172 increase, as going from the first portions 1211 and 1721 to the third portions 1213 and 1723.

In the second back impurity regions 172, the second back impurity regions 172 prevent or reduce the movement of charges (e.g., holes) to the back surface of the substrate 110 by a potential barrier resulting from a difference between the impurity doping concentrations of the substrate 110 and the third portions 1723 with the greatest impurity doping concentration in the same manner as the third portion 1913 the front impurity region 191, but facilitate the movement of charges (for example, electrons) to the second back impurity regions 172. Thereby, each third portion 1723 of the second back impurity regions 172 functions as a back surface field region. Thus, the third portions 1723 of the second back impurity regions 172 reduce a loss amount of charges by a recombination and/or a disappearance of electrons and holes in or around the second back impurity regions 172 due to holes that have moved to the second back impurity regions 172, and accelerate the movement of electrons to the second back impurity regions 172, thereby increasing an amount of electrons moving to the second back impurity regions 172. Accordingly, an efficiency of the solar cell 11 is improved.

Thereby, a formation of separate passivation region made of intrinsic amorphous silicon for performing the passivation function is not required, such that the time and cost for manufacturing the solar cell 11 are reduced.

Because the substrate 110 and each emitter region (i.e., each first back impurity region) 121 form the p-n junction, the emitter regions 121 may be of the n-type when the substrate 110 is of the p-type in another embodiment unlike the embodiment described above. In this instance, the electrons move to the first back impurity regions 121, and the holes move to the second back impurity regions 172.

When the plurality of first back impurity regions 121 are of the p-type, the first back impurity regions 121 may be doped with impurities of a group III element. On the contrary, when the first back impurity regions 121 are of the n-type, the first back impurity regions 121 may be doped with impurities of a group V element.

In the embodiment of the invention, a width W1 of each first back impurity region 121 is different from a width W2 of each second back impurity region 172. That is, the width W2 of each second back impurity region 172 is greater than the width W1 of each first back impurity region 121. Thereby, a surface size of portions of the substrate 110 which is covered with the second back impurity regions 172 increases to more improve the back surface field effect obtained by the third portions 1723 of the second back impurity regions 172.

However, in an alternative embodiment of the invention, the width W1 of each first back impurity region 121 may be greater than the width W2 of each second back impurity region 172. In this instance, since an area of the p-n junction increases, an amount of the electrons and holes generated in the area of the p-n junction increases, and the collection of holes having mobility less than that of electrons is facilitated.

As an example, the first and second back impurity regions 121 and 172 may be also formed using silane (SiH₄) and hydrogen (H₂), to form an amorphous silicon layer in the same manner as the front impurity region 191. In this instance, for forming the first back impurity regions 121 with an impurity of the p-type doped thereinto, diborane (B₂H₆) may be used as an impurity doping material, and for forming the second back impurity regions 172 with an impurity of the n-type doped thereinto, phosphine (PH₃) may be used as an impurity doping material. The impurity doping materials for the n-type and the p-type may be changed or may be different from those listed above.

Like the front impurity region 191, by changing an amount of the impurity doping materials injected into chambers for forming the first and second back impurity regions 121 and 172 in process of time (or in situ), the first to third portions 1911 to 1913 of the first and second back impurity regions 121 and 172, each which has a desired thickness and a desired impurity doping concentration may be formed on the substrate 110. The first and second back impurity regions 121 and 172 may be formed in separate chambers, respectively or in the same chamber.

When the total thickness of each first back impurity region 121 is more than about 5 nm, the p-n junction is more stably formed and the movement of charges (electrons and holes) is more easily performed to improve the efficiency of the solar cell 1. When the total thickness of each second back impurity regions 172 is more than about 5 nm, fields for the back surface field function are more stably generated to more improve the back surface field function.

When the total thickness of each of the first and second back impurity regions 121 and 172 is less than about 25 nm, amounts of light absorbed in the first and second back impurity regions 121 and 172 are reduced. Hence, amounts of light re-incident in the substrate 110 may increase. When the total thickness of each first back impurity region 121 is less than about 25 nm, a sheet resistance of each first back impurity region 121 increases and thereby a serial resistance of the solar cell 11 decreases, to improve the efficiency of the solar cell 11.

In the example embodiment of the invention, a separate passivation region is not required, but the passivation function and the back surface field function are performed by varying amounts of the impurity doping materials when forming the first and second back impurity regions 121 and 172. Thereby a separate chamber for the separate passivation region is not necessary, to decrease the time and cost for manufacturing the solar cell 11.

Furthermore, the separate passivation region made of an intrinsic semiconductor does not exist between the substrate 110 and the plurality of first back impurity regions 121 and between the substrate 110 and the plurality of second back impurity regions 172, and thereby, energy band gap differences between the substrate 110 and the plurality of first back impurity regions 121, and between the substrate 110 and the plurality of second back impurity regions 172 decrease. Accordingly, the energy band gaps between the substrate 110 and the plurality of first back impurity regions 121 and between the substrate 110 and the plurality of second back impurity regions 172 are gently, incrementally or gradually changed. Thus, the charges (electrons and holes) easily move from the substrate 110 to the first and second back impurity regions 121 and 172.

In addition, when the thickness of the separate passivation region increases in a case in which that the separate passivation region is positioned between the substrate 110 and the first and second electrodes 141 and 142, tunneling of charges is prevented or reduced by the separate passivation region, and charges pass through the separate passivation region made of the intrinsic semiconductor and move to the electron part 140. Thereby, the movement of charges to the electrode part 140 is disturbed to decrease the efficiency of the solar cell 11. In particular, an amount of holes moved to the first back impurity regions 121 further decreases since the mobility of the holes is less than that of the electrons.

Since the first and second back impurity regions 121 and 172 of the embodiment of the invention do not contain intrinsic semiconductor portions, the mobility of charges that moves from the substrate 110 to the first and second back impurity regions 121 and 172 increases. In addition, since the first and second back impurity regions 121 and 172 are directly contacted with the substrate 110 not through the separate intrinsic semiconductor region, movement distances of the charges are reduced to improve the efficiency of the solar cell 11.

As described, the electrode part 140 includes the plurality of first electrodes 141 positioned on the third portions 1213 of the plurality of first back impurity regions 121 functioning as the emitter regions and extending along the underlying first back impurity regions 121, and the plurality of second electrodes 142 positioned on the third portions 1723 of the plurality of second back impurity regions 172 and extending along the underlying second back impurity regions 172.

Each first electrode 141 collects charges (for example, holes) moving to the corresponding first back impurity region 121.

Each second electrode 142 collects charges (for example, electrons) moving to the corresponding second back impurity region 172.

In FIG. 1, the first and second electrodes 141 and 142 have different planar shapes or sheet shapes as the first back and second impurity regions 121 and 172 underlying the first and second electrodes 141 and 142. However, they may have the same planar shapes. As a contact area between the first and second back impurity regions 121 and 172 and the respective first and second electrodes 141 and 142 increases, a contact resistance therebetween decreases. Hence, the charge transfer efficiency of the first and second electrodes 141 and 142 increases.

In particular, the first and second electrodes 141 and 142 are in contact with the third portions 1213 and 1723 of the greatest impurity doping concentration. Thus, the charge transfer ability from the third portions 1213 of the first back impurity regions 121 to the first electrodes 141, and the charge transfer ability from the third portions 1723 of the second back impurity regions 172 to the second electrodes 142 are improved. Thereby, amounts of charges moved from the first and second back impurity regions 121 and 172 to the first and second electrodes 141 and 142 more increases, respectively.

The plurality of first and second electrodes 141 and 142 may be formed of at least one conductive material selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used. As described above, because the plurality of first and second electrodes 141 and 142 are formed of the metal material, the plurality of first and second electrodes 141 and 142 reflect light passing through the substrate 110 onto the substrate 110.

The solar cell 11 having the above-described structure is a solar cell in which the plurality of first and second electrodes 141 and 142 are positioned on the back surface of the substrate 110, on which light is not incident, and the substrate 110 and the plurality of first back impurity regions (that is, the emitter regions) 121 are formed of different kinds of semiconductors. An operation of the solar cell 11 is described below.

When light is irradiated onto the solar cell 11, sequentially passes through the anti-reflection layer 130 and the front impurity region 191, and is incident on the substrate 110, a plurality of electrons and a plurality of holes are generated in the substrate 110 by light energy based on the incident light. In this instance, because the front surface of the substrate 110 is the textured surface, a reflectance of light at the front surface of the substrate 110 is reduced. Further, because both a light incident operation and a light reflection operation are performed on the textured surface of the substrate 110, absorption of light increases and the efficiency of the solar cell 11 is improved. In addition, because a reflection loss of the light incident on the substrate 110 is reduced by the anti-reflection layer 130, an amount of light incident on the substrate 110 further increases.

By the p-n junction of the substrate 110 and the first back impurity regions 121, and the holes move to the p-type first back impurity regions 121 and the electrons move to the n-type second back impurity regions 172. The holes moving to the p-type first back impurity regions 121 are collected by the first electrodes 141, and the electrons moving to the n-type second back impurity regions 172 are collected by the second electrodes 142. When the first electrodes 141 and the second electrodes 142 are connected to each other using electric wires, current flows therein to thereby enable use of the current for electric power.

The solar cell 11 of the embodiment of the invention is not required to include the separate intrinsic semiconductor layer (for example, the intrinsic amorphous silicon layer) for obtaining the front and back surface field effects and the passivation effect at the surface of the substrate 110. The intrinsic semiconductor layer has a high resistance and does not contain an impurity for the front and back surface field effects and the passivation effect. Thereby, a serial resistance of the solar cell 11 decreases and fill factor of the solar cell 11 increases, to thereby improve the efficiency of the solar cell 11.

In embodiments of the invention, the first portions 1211 of the first back impurity region and the first portions 1721 of the second back impurity regions 172 are portions having relatively low doping concentrations, so that they are intentionally doped regions and not intrinsic. The first back impurity region 121 and second back impurity regions 172 are locally formed regions of the solar cell 11 that is able to perform both a local passivation function and a local surface field function over a common portion of the substrate 110.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell, comprising:
a crystalline semiconductor substrate containing a first impurity of a first conductive type;
a first non-crystalline impurity semiconductor region directly contacting with the crystalline semiconductor substrate to form a p-n junction with the crystalline semiconductor substrate and comprising a first portion in which a second impurity of a second conductive type is doped with a first impurity doping concentration and a second portion in which the second impurity is doped with a second impurity doping concentration, the first impurity doping concentration being less than an impurity doping concentration of the crystalline semiconductor substrate and the second impurity doping concentration being greater than the impurity doping concentration of the crystalline semiconductor substrate;
a first electrode connected to the first non-crystalline impurity semiconductor region; and
a second electrode connected to the crystalline semiconductor substrate.

2. The solar cell of claim 1, wherein the first portion is positioned on the crystalline semiconductor substrate and the second portion is positioned on the first portion.

3. The solar cell of claim 1, wherein the first impurity doping concentration is substantially 1×10¹⁰ atoms/cm³ to 1×10¹⁵ atoms/cm³ and the second impurity doping concentration is substantially 1×10¹⁸ atoms/cm³ to 1×10²¹ atoms/cm³.

4. The solar cell of claim 3, wherein the first portion of the first non-crystalline impurity semiconductor region has a thickness equal to a thickness of the second portion of the first non-crystalline impurity semiconductor region.

5. The solar cell of claim 1, wherein the first non-crystalline impurity semiconductor region further comprises a third portion positioned between the first portion of the first non-crystalline impurity semiconductor region and the second portion of the first non-crystalline impurity semiconductor region and has a third impurity doping concentration different from the first and second impurity doping concentrations.

6. The solar cell of claim 5, wherein the third impurity doping concentration is greater than the first impurity doping concentration and less than second impurity doping concentration.

7. The solar cell of claim 6, wherein the third impurity doping concentration is substantially 1×10¹⁶ atoms/cm³ to 1×10¹⁷ atoms/cm³.

8. The solar cell of claim 5, wherein the third portion of the first non-crystalline impurity semiconductor region has a thickness that is half of a thickness of the first portion of the first non-crystalline impurity semiconductor region.

9. The solar cell of claim 8, wherein the thickness of the first portion is equal to the thickness of the second portion.

10. The solar cell of claim 1, wherein the first non-crystalline impurity semiconductor region is positioned on a surface of the crystalline semiconductor substrate, on which light is not incident.

11. The solar cell of claim 1, further comprising a second non-crystalline impurity semiconductor region comprising a first portion in which a third impurity of a third conductive type is doped with a third impurity doping concentration and a second portion in which the third impurity is doped with a fourth impurity doping concentration, the fourth impurity doping concentration being greater than the third impurity doping concentration.

12. The solar cell of claim 11, wherein the first portion of the second non-crystalline impurity semiconductor region is positioned on the crystalline semiconductor substrate and the second portion of the second non-crystalline impurity semiconductor region is positioned on the first portion of the second non-crystalline impurity semiconductor region.

13. The solar cell of claim 11, wherein the third impurity doping concentration is equal to the first impurity doping concentration and the fourth impurity doping concentration is equal to the second impurity doping concentration.

14. The solar cell of claim 11, wherein the second non-crystalline impurity semiconductor region further comprises a third portion positioned between the first portion of the second non-crystalline impurity semiconductor region and the second portion of the second non-crystalline impurity semiconductor region and has a fifth impurity doping concentration different from the third and fourth impurity doping concentrations.

15. The solar cell of claim 11, wherein the second non-crystalline impurity semiconductor region is positioned on a same surface as the first non-crystalline impurity semiconductor region and is separated from the first non-crystalline impurity semiconductor region, and
the second electrode is connected to the crystalline semiconductor substrate through the second non-crystalline impurity semiconductor region.

16. The solar cell of claim 15, wherein the second non-crystalline impurity semiconductor region is positioned on a surface of the crystalline semiconductor substrate, on which light is not incident.

17. The solar cell of claim 16, wherein the second non-crystalline impurity semiconductor region faces the first non-crystalline impurity semiconductor region with respect to the crystalline semiconductor substrate and is further positioned on a different surface from the first non-crystalline impurity semiconductor region.

18. The solar cell of claim 11, wherein the second non-crystalline impurity semiconductor region is positioned on a different surface from the first non-crystalline impurity semiconductor region.

19. The solar cell of claim 18, wherein the second non-crystalline impurity semiconductor region is positioned on a surface of the crystalline semiconductor substrate, on which light is incident.

20. The solar cell of claim 11, wherein a width of the second non-crystalline impurity semiconductor region is greater than a width of the first non-crystalline impurity semiconductor region.
